(19) United States
(12) Patent Application Publication
(10) Pub. No.: US 2019/0122926 A1
(43) Pub. Date: Apr. 25, 2019

(54) Self-Aligned Shielded Trench MOSFETs and Related Fabrication Methods

(71) Applicant: MaxPower Semiconductor Inc., San Jose, CA (US)

(72) Inventors: Mohamed N. Darwish, Campbell, CA (US); Jun Zeng, Torrance, CA (US); Richard A. Blanchard, Los Altos, CA (US)

(73) Assignee: MaxPower Semiconductor Inc., San Jose, CA (US)

(21) Appl. No.: 16/115,312

(22) Filed: Aug. 28, 2018

Related U.S. Application Data
(60) Provisional application No. 62/556,201, filed on Sep. 8, 2017.

(51) Int. Cl. H01L 21/768; H01L 29/78; H01L 29/417; H01L 29/40; H01L 29/49; H01L 29/423; H01L 29/10; H01L 21/28; H01L 21/765; H01L 21/265; H01L 21/324; H01L 29/66

(52) U.S. Cl. CPC H01L 21/76897; H01L 29/66734; H01L 29/41741; H01L 29/404; H01L 29/407; H01L 29/4916; H01L 29/42376; H01L 29/1095; H01L 21/28035; H01L 21/28114; H01L 21/765; H01L 21/26513; H01L 21/324; H01L 29/401; H01L 29/7813

(57) ABSTRACT

Structures and fabrication methods for increasing the density of trench transistor devices and the like. During fabrication of a trench transistor device, a vertical protrusion (or “hat”) of oxide is left in place above the gate trench. This vertical protrusion is self-aligned to the gate trench, and is used to define the positions of sidewall spacers (made e.g. of silicon nitride). These sidewall spacers define a space outward from the edge of the gate trench; by performing a recess etch which is delimited by these sidewall spacers, the resistance of the source contact and the body contact is minimized. The spacing between the gate trench and the recessed-contact field-plate trench can therefore be minimized and well controlled, which improves density without degrading on-resistance nor breakdown voltage.

### CROSS-REFERENCE

Priority is claimed from U.S. application 62/556,201, which is hereby incorporated by reference.

### BACKGROUND

The present application relates to trench transistor structures which include recessed field plates, and to methods for fabricating these and analogous devices.

Note that the points discussed below may reflect the hindsight gained from the disclosed inventions, and are not necessarily admitted to be prior art.

Power MOSFETs are widely used as switching devices in many electronic applications. In order to minimize conduction power losses it is desirable that power MOSFETs have low specific on-resistance (Rₛₚ) which is defined as the on-resistance area product. (An equivalent metric is on-state conductance per unit area.) To achieve a lower specific on-resistance (Rₛₚ), a higher packing density or number of cells per unit area is required; that is, the cell pitch has to decrease. As the cell density increases the associated specific capacitances (i.e. capacitances per unit area), such as gate-drain capacitance C_{gd} and gate-source capacitance C_{gs}, also (undesirably) increase.

To minimize switching losses it is desirable to have a switch with lower capacitances C_{gd} and gate-source C_{gs}. (Equivalently, since these capacitances are not perfectly linear, it can be more convenient to refer to gate-drain charge Q_{gd} and gate charge Q_{g}.)

A Recessed Field Plate (RFP) trench MOSFET structure with thick oxide formed at the bottom of the gate trench as shown in FIG. 2 provides low Rₛₚ, Q_{gd}, and Q_{g}. Other structures with a split-gate or Embedded Shielded Field Plate (ESFP) have also been proposed. Examples of such structures were disclosed in U.S. Pat. Nos. 7,843,004, 8,076,719 and 8,581,341, which are all hereby incorporated by reference.

### Self-Aligned Shielded Trench MOSFETs and Related Fabrication Methods

The present inventors have realized that, during fabrication of a trench transistor device, a vertical protrusion (or “hat”) of oxide (or other suitable material) can be left in place above the trench which contains the transistor gate. This vertical protrusion is self-aligned to the gate trench, and is used to define the positions of sidewall spacers (made e.g. of silicon nitride). These sidewall spacers define a space outward from the edge of the gate trench; by performing a recess etch which is delimited by these sidewall spacers, the resistance of the source contact and the body contact is minimized. The spacing between the gate trench and the recessed contact can therefore be controlled and minimized, which improves density without degrading on-resistance nor breakdown voltage.

The resulting device is different from previous devices, because lateral dimensions around the gate are self-aligned. Normally some degree of unpredictable misalignment will occur in a state-of-the-art microelectronic wafer (and in the dies which are part of the wafer). However, where self-alignment is used, this variation essentially disappears. The lateral distance between the walls of the gate trench and the recess over the field plate trench is NOT defined by lithography in any way, and does not show the small misalignments resulting from lithography. This means that the devices built according to the present application are different from all previous devices of this kind; but the difference is most easily understood by reviewing the process steps.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1A shows a trench MOSFET structure with self-aligned contacts.

FIG. 1B shows another example of a trench MOSFET structure with self-aligned contacts.

FIG. 2 shows a previously proposed Recessed Field Plate (RFP) trench MOSFET structure with thick oxide formed at the bottom of the gate trench.

FIG. 3 shows a structure which is generally somewhat similar to that of FIG. 1A, but with an Embedded Shielded Field Plate (ESFP).

FIG. 4A and FIG. 4B show two versions of a Self-Aligned Contact-Split gate Shield Field Plate Trench MOSFET.

FIG. 5 shows another Self-Aligned Contact Shield Field Plate Trench MOSFET with no thick bottom oxide at the gate trench.

FIG. 6A shows initial steps in one example of making the device of FIG. 1A.

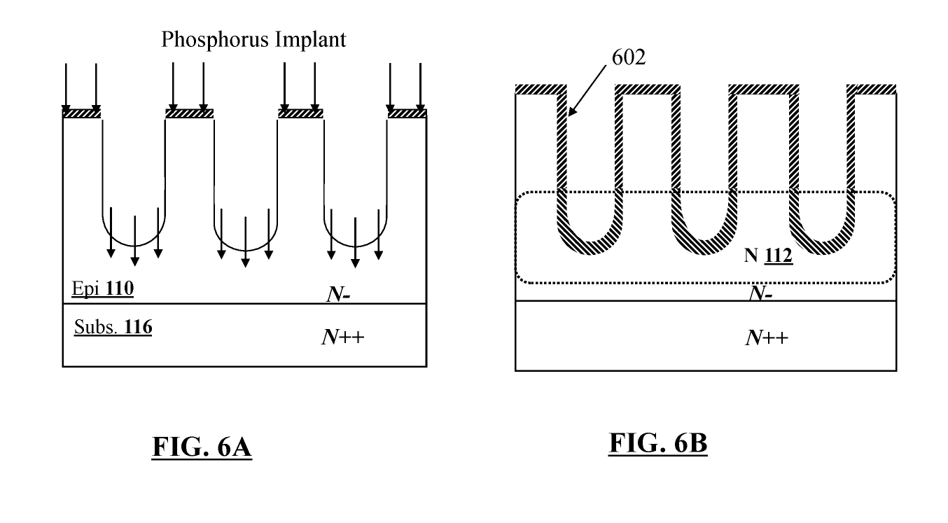

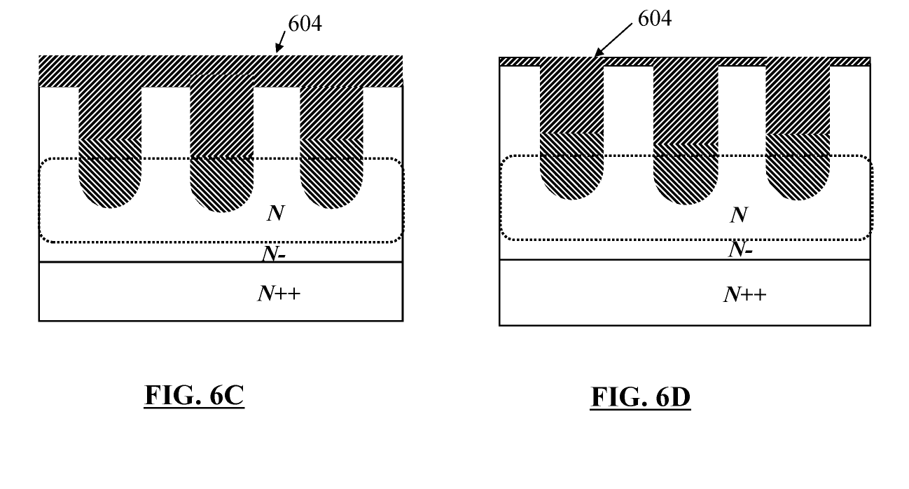

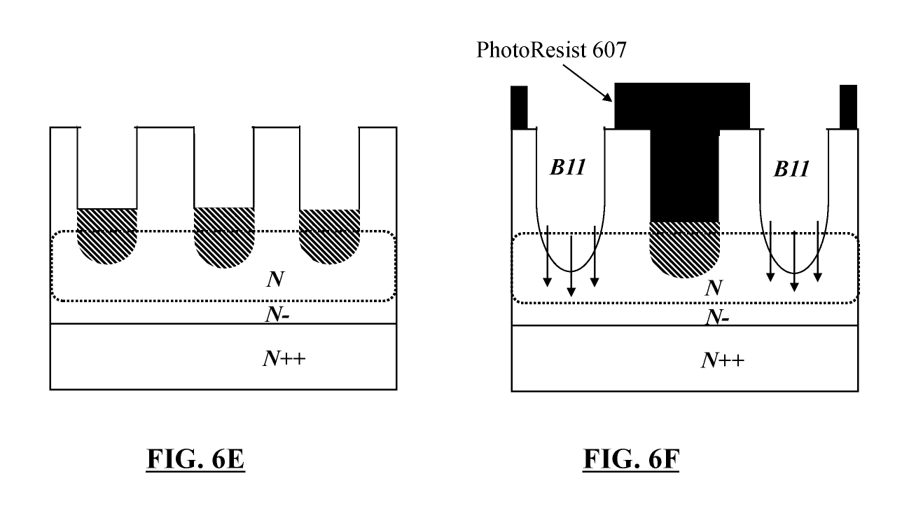

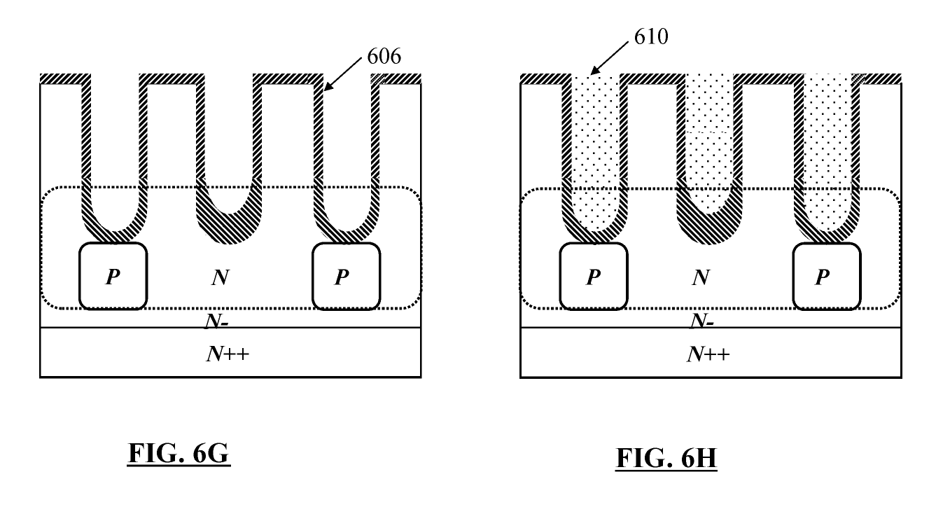

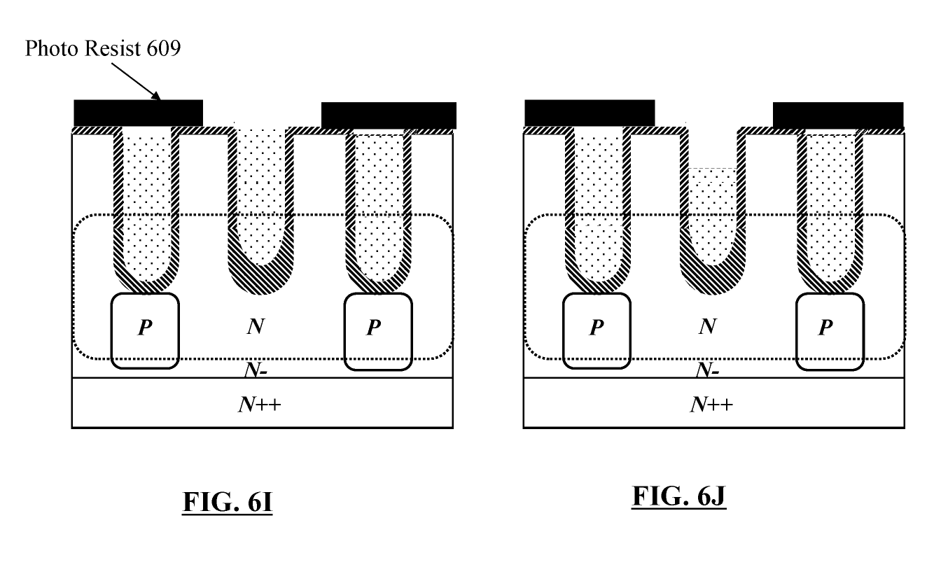

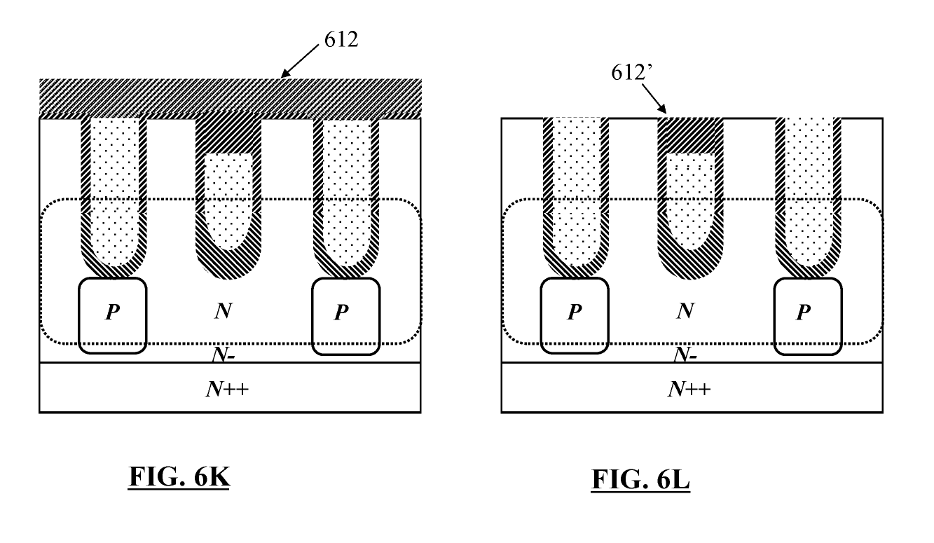

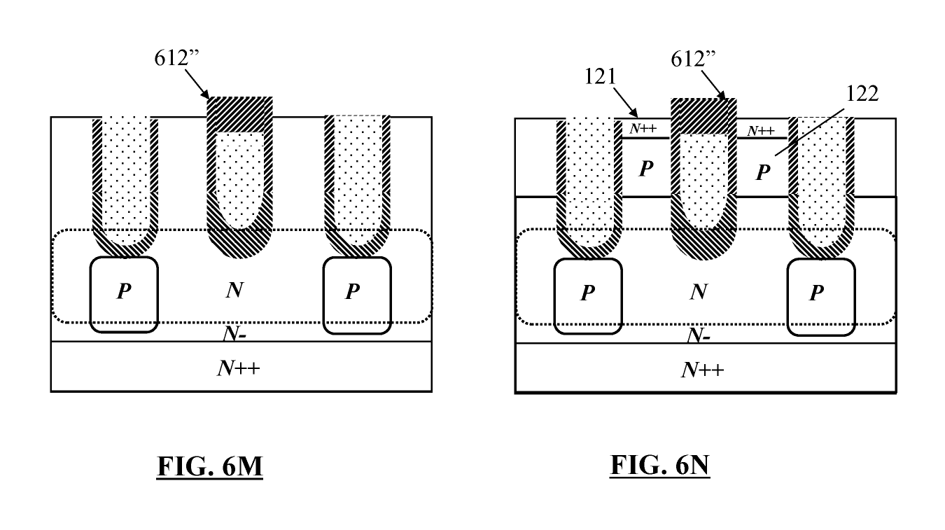

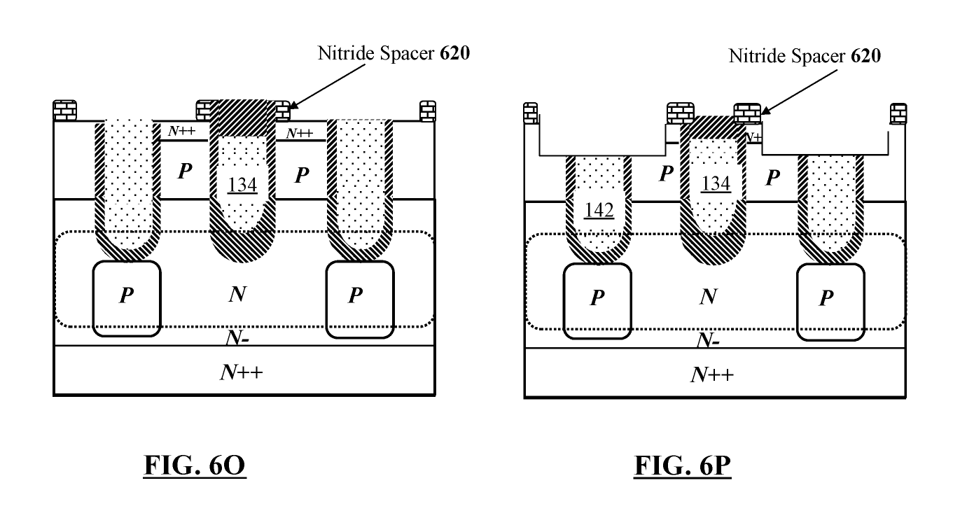

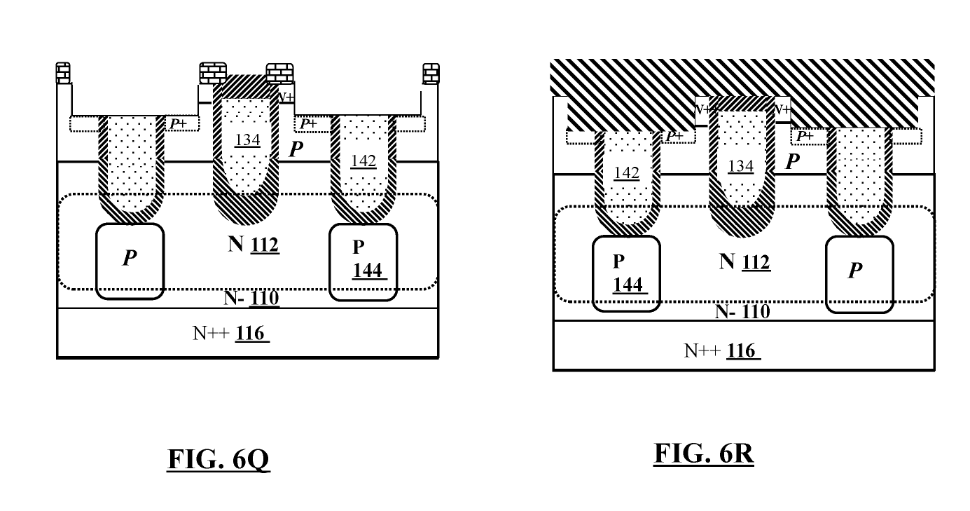

Sequential FIGS. 6B-6F depict the steps of forming thick bottom dielectric (e.g. oxide) in the gate trench, and p-type shield region below the RFP trench.

Further FIGS. 6G-6H show the steps of forming gate dielectric (e.g. oxide), filling the trench with a conductive material (for example doped polysilicon), and etching back the conductive material to the level of semiconductor surface.

Further FIGS. 6I-6J show an additional recess etched in the gate trench using a photoresist mask.

Further FIGS. 6K-6L show forming a planar top dielectric layer (e.g. oxide).

Subsequent FIG. 6M shows how a vertical protrusion (or hat shape) is self-aligned to the gate trench.

Subsequent FIG. 6N shows formation of source and body regions.

Subsequent FIG. 6O shows how the vertical protrusion (or “hat”) is used to create spacers which are self-aligned to the gate trench.

Subsequent FIGS. 6P-6R shows later steps in fabrication, including how the metallization is self-aligned to the gate trench.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

The present application discloses new power transistor structures, and new approaches to fabricating such devices.

Power MOSFETs are widely used as switching devices in many electronic applications. In order to minimize conduction power losses it is desirable that power MOSFETs have low specific on-resistance (Rₛₚ) which is defined as the on-resistance area product. (An equivalent metric is on-state conductance per unit area.) To achieve a lower specific on-resistance Rₛₚ, a higher packing density or number of cells per unit area is required; that is, the cell pitch has to decrease. As the cell density increases the associated specific capacitances (i.e. capacitances per unit area), such as gate-drain capacitance C_{gd} and gate-source capacitance C_{gs}, also (undesirably) increase.

To minimize switching losses it is desirable to have a switch with lower gate-drain and gate-source capacitances C_{gd} and C_{gs}. (Equivalently, since these capacitances are not perfectly linear, it can be more convenient to refer to gate-drain charge Q_{gd} and gate charge Q_{g}.)

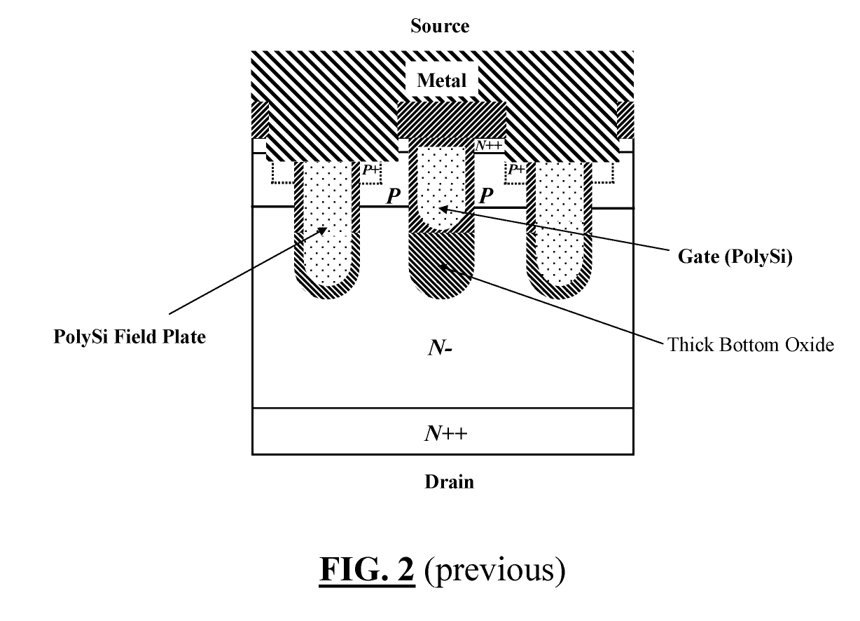

A Recessed Field Plate (RFP) trench MOSFET structure with thick oxide formed at the bottom of the gate trench as shown in FIG. 2 provides low Rₛₚ, Q_{gd}, and Q_{g}. Other structures with a split-gate or Embedded Shielded Field Plate (ESFP) (collectively known as a split poly configuration) have also been proposed. Examples of such structures were disclosed in U.S. Pat. Nos. 7,843,004, 8,076,719 and 8,581,341, which are all hereby incorporated by reference.

To reduce the cell pitch, the trench and contact widths have to become narrower and the distance between the contact and gate trench smaller. A narrower contact width results in a higher contact aspect ratio, which makes it difficult to be filled with metal. Furthermore, the process of controlling a small critical dimension between the contact and gate trench is difficult to realize in production due to misalignment.

Misalignment between the contact and the trench, together with the contact width and its high aspect ratio, set constraints on achieving higher cell density transistors. What is needed is a high-cell-density RFP power MOS transistor with a small critical dimension between the contact and gate trench that is easier to control and a contact with an aspect ratio that enables metal filling.

The present application discloses new power MOSFET structures and methods of fabrication. The new structures provide high cell density with improved conduction and capacitance characteristics.

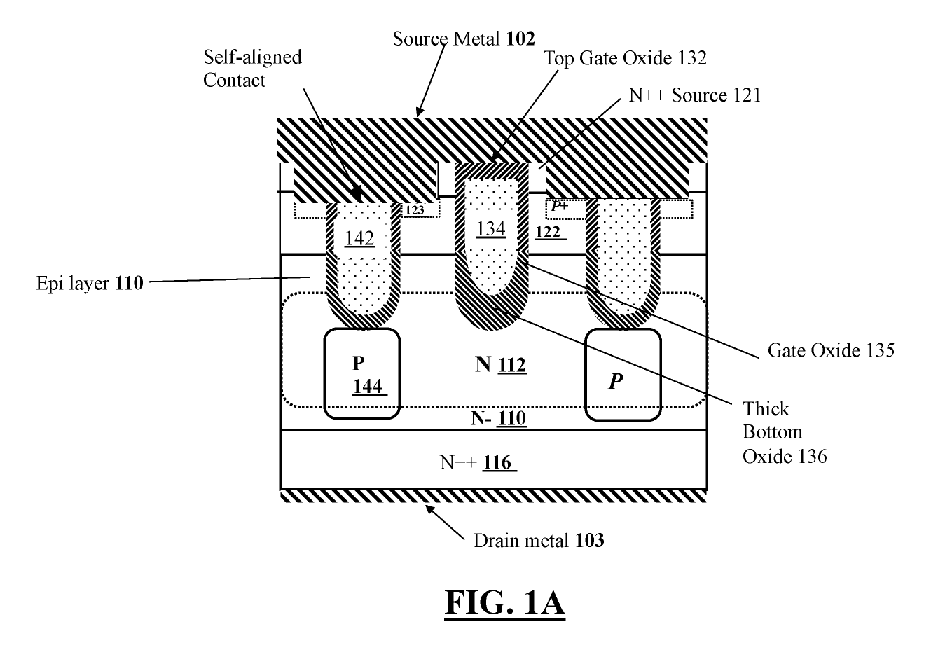

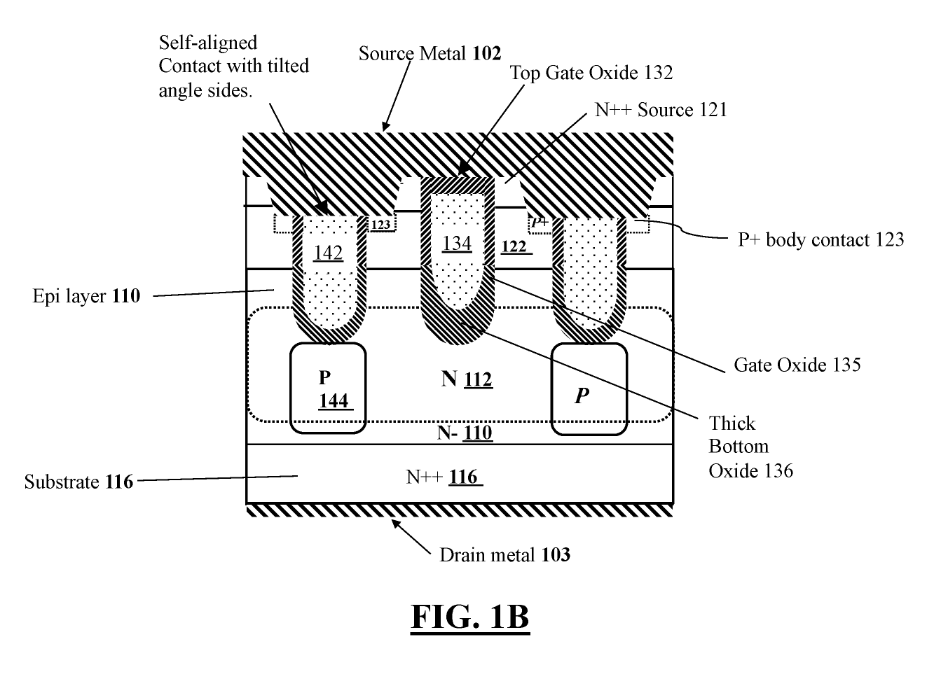

FIG. 1A shows one embodiment, in which a trench MOSFET structure has a substantially planar top gate oxide surface and self-aligned contacts. Note that this Figure shows two kinds of trenches: the gate trench (at the center of this drawing) contains a gate electrode 134, and the “RFP” trenches (to the left and right of the gate trench) contain a recessed field plate 142. The gate electrode is connected elsewhere (not shown) to a gate drive input.

In operation, when the gate electrode 134 is driven sufficiently high, it will invert a portion of the p-type body region 122. (Thus mobile electrons will be present where the gate oxide 135 meets the body region 122.) This permits electrons to flow from the n+ source region 121, through the inverted portion of the body 122, through the drift region n-type epitaxial layer 110 and the n-type enhanced region 124 within it, down to the n++ drain region 116. Thus, when the drain metal is connected to a positive voltage, the conventional current flows from drain metal 103, through regions 116, 110, 112, 110 again, 122, and 121, to source metal 102. Besides the source region 121, source metal 102 also makes ohmic contact to the body 122 (through p+ body contact region 123) and to the recessed field plate 142.

Note that the gate electrode 134 is also isolated by a top gate oxide 132 and a thicker bottom oxide 136.

It is important to note that the dielectric layer above the top gate oxide 132 in FIG. 1A is substantially planar with respect to the mesa surface resulting in an adequate contact aspect ratio for easier metal filling. Furthermore, the self-aligned contact results in small and controlled spacing between contact and the gate trench. Therefore the structure in FIG. 1A provides lower Rₛₚ, Q_{g} and Q_{gd} due to the higher cell density, thick bottom gate oxide and RFP shielding effect.

It should be noted that the specific materials and dimensions mentioned are merely illustrative, and are disclosed to help understand the invention. For example, the gate dielectric is preferably a grown silicon dioxide layer, but alternatively different materials or techniques can be used. The vertical protrusion (or “hat”) is formed from a plug of a deposited dielectric material, which in this example is an oxide of silicon; but alternatively other materials and/or other deposition steps can be used. The spacers around the hat are silicon nitride in the following example, but alternatively a different material can be used, as long as that material can be etched selectively with respect to the material which forms the vertical protrusion (or “hat”).

FIG. 1B shows another Self-Aligned Contact trench MOSFET which is somewhat similar to that shown in FIG. 1A, except that the recessed contact sides are etched using a tilted angle (trapezoidal shape) process, such that the bottom side of the tapered contact is smaller than the top side and the sides are sloping. This structure has a larger distance between the p+ body contact region 123 and the gate trench and does not affect the p-body doping at the channel. This feature makes the threshold voltage Vth less sensitive to process variation due to the proximity of the p+ body contact to the channel. This still preserves the self-alignment relations described above.

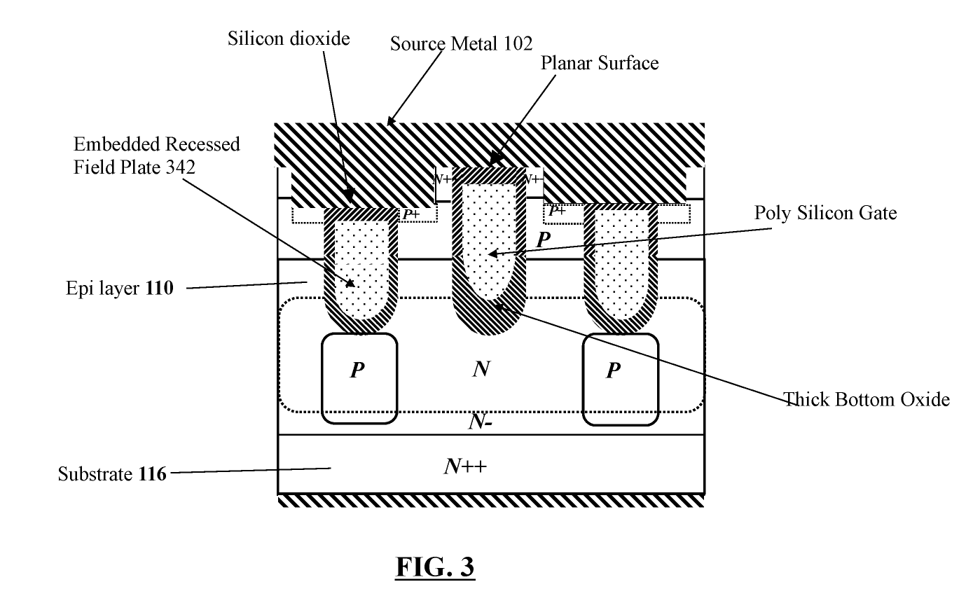

FIG. 3 shows a structure which is generally somewhat similar to that of FIG. 1A, but with an Embedded Shielded Field Plate (ESFP) structure, where a dielectric layer exists over the field plate 342. The field plate 342 is preferably connected to the source contact in some area of the device (not shown).

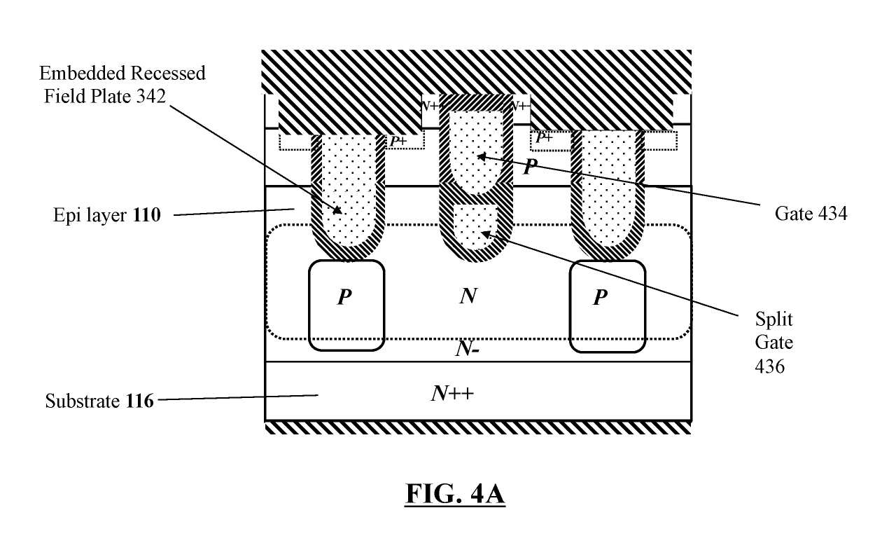

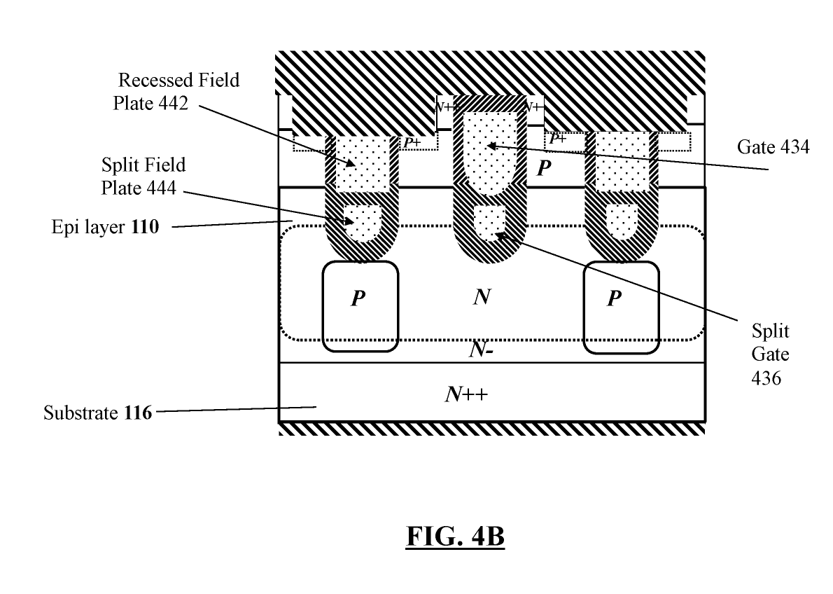

FIG. 4A shows a Self-Aligned Contact Split-gate Shield Field Plate Trench MOSFET. This structure is generally somewhat similar to that of FIG. 1A, but with a Split Gate (SG) structure. The bottom electrode 436 in the gate trench lies beneath the gate electrode 434, and is connected to the source contact or the RFP electrode in at least some areas of the device (not shown).

FIG. 4B shows another Self-Aligned Contact Split-gate Shield Field Plate Trench MOSFET. This structure is generally somewhat similar to that of FIG. 4A, but with a Split Field Plate electrode. The bottom electrode 444 in the RFP trench lies beneath the upper field plate 442, is connected to the source electrode in some areas of the device (not shown).

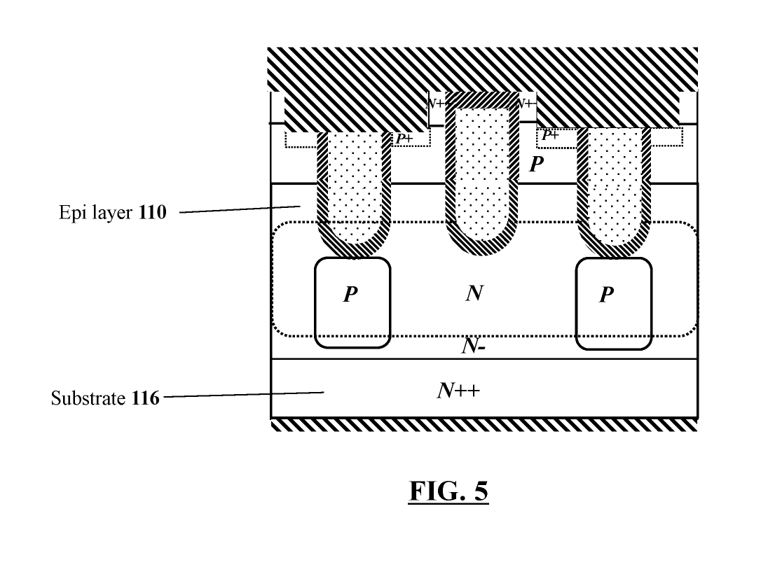

FIG. 5 shows another Self-Aligned Contact Shield Field Plate Trench MOSFET. This structure is generally somewhat similar to that of FIG. 1, but without the thick bottom oxide. This provides a lower Rsp, at the price of higher capacitance and worse gate characteristics.

Preferred methods of making the structure shown in FIG. 1 are described below and as shown in FIG. 6A-6R. These methods can also be adapted to the structures of FIGS. 3 and 4A-4B.

FIG. 6A shows the steps of forming the trench and local N-enhancement region in a N/N+ semiconductor starting material such as silicon. Starting with an epitaxial wafer (n on n+ in this example), the illustrated structure results from the steps of: Trench Mask; Trench Etch (e.g. to a depth of about 1.1 microns); and an implant of phosphorus. Phosphorus is preferred for this implant due to its high diffusivity, but optionally and less preferably antimony or arsenic can be admixed or substituted. Other donor dopants can be used if a different semiconductor material is used.

FIGS. 6B-6F depict the steps of forming thick bottom oxide in gate trench and p-shield region below the RFP trench.

After the partially completed structure of FIG. 6A, a sacrificial oxide 602 is formed, and a furnace or RTA step is performed to drive and anneal the phosphorus implant shown in FIG. 6A. This forms the enhanced conductivity region 112 seen in FIG. 1A. This improves the on-state conductivity of the device, without degrading the body junction. This results in the intermediate structure of FIG. 6B.

Next, a thin sealing oxide is grown or deposited overall, e.g. to 100 nm thickness. A thick planar oxide 604 is formed overall, e.g. by HDP (High Density Plasma Chemical Vapor Deposition) to about 1000 nm thickness. This results in the intermediate structure of FIG. 6C.

The thick oxide 604 is generally planar, but preferably it is now subjected to CMP (chemical-mechanical polishing), to ensure that its top surface is planar and smooth. In the example shown, the resulting thickness of the oxide 604 is about 300 nm. This results in the intermediate structure of FIG. 6D.

An oxide etch is now performed, so that the thickness of oxide remaining in the trench is only about e.g. 400 nm. This results in the intermediate structure of FIG. 6E.

A patterning step now provides a temporary photoresist layer 607 which covers the gate trenches, but not the recessed-field-plate (RFP) trenches. An oxide etch is now performed, so that oxide is cleared from the RFP trenches, and dopant atoms are then implanted there. In this example, the dopant is boron ¹¹B, but alternatively another species can be used. This implant will form the pocket regions 144, so the dose and energy can be adjusted, as will be apparent to device engineers of ordinary skill, to achieve the desired doping and dimensions of the pocket region 144. This results in the intermediate structure of FIG. 6F.

FIGS. 6G-6H show the steps of forming gate oxide and filling the trench with a conducting material (for example doped polysilicon/polycrystalline silicon) and etching back the polysilicon to the level of semiconductor surface.

After the structure of FIG. 6F, a gate oxide 606 is grown on exposed silicon. This can be e.g. 50 nm thick. With a silicon wafer the grown oxide will be essentially pure SiO₂, but with other semiconductors a different composition can be grown or deposited. This results in the intermediate structure of FIG. 6G.

Polysilicon is then deposited conformally, and etched back anisotropically, almost to the point of exposing horizontal surfaces. The polysilicon is preferably doped after deposition, but alternatively some degree of in situ doping can be used. Preferably the polysilicon is etched further, to produce a recess of 50 nm at the trench tops. Optionally, depending on what connections and function are being formed in other parts of the wafer, a mask (not shown) can be formed before processing of the polysilicon layer is complete. These steps result in the intermediate structure of FIG. 6H.

FIGS. 6I-6J show an additional polysilicon recess etch in the gate trench using a photoresist mask.

After the steps shown in FIG. 6H, a patterned photoresist layer 609 is now formed, exposing the gate trench but not the RFP trench. This results in the intermediate structure of FIG. 6I.

A selective polysilicon etchback is now performed, to produce a recess of e.g. 350 nm in the gate trench. This results in the intermediate structure of FIG. 6J.

FIGS. 6K-6L show depositing top oxide layer and etching the oxide back, preferably using Chemical-Mechanical-Polish (CMP) to make the top oxide in the gate trench planar with the semiconductor surface.

After the steps leading to FIG. 6J, a planar dielectric layer 612 is now formed. This can be, in a preferred example, SiO₂ deposited to about 600 nm thickness. This results in the intermediate structure of FIG. 6K.

The dielectric 612 is now removed from flat areas overall, preferably by CMP (chemical-mechanical polishing). The CMP uses a chemistry which preferentially removes oxide, i.e. which is selective to silicon. The thickness removed is approximately the same as the total thickness deposited, i.e. 600 nm in this example. Since a recess was previously present in the gate trench, a remnant 612′ of the dielectric 612 remains as a plug in the gate trench. This plug will be important, as described below. At this point, the RFP trenches remain filled with polysilicon. These steps result in the intermediate structure of FIG. 6L.

After the structure of FIG. 6L has been completed, silicon and polysilicon are etched back overall. In this example, the monocrystalline silicon and polysilicon are etched back by about 200 nm. The etch used preferably has about 7:1 selectivity to oxide, so the oxide thickness will be reduced by only about 30 nm while the polysilicon is etched back by about 200 nm. This is an important step, since the dielectric (oxide) remnant 612″ now stands out above the surface of the semiconductor material. This remnant 612″ will be referred to as a vertical protrusion (or “hat”), and has a substantially flat top surface and substantially vertical sides. This results in the intermediate structure of FIG. 6M.

After the structure of 6M has been formed, dopants for the p-body region 122 and n+ source region 121 are introduced, preferably by ion implantation.

In the preferred example, a masking layer is formed to expose only some locations for formation of the n+ source regions 121. Now arsenic ions are implanted, e.g. with a dose of 8E15 (8×10′⁵) cm⁻² at an energy of e.g. 80 keV. (Alternatively, antimony ions can be used instead of or in addition to arsenic ions, though no significant advantage from this substitution is expected.) Preferably this is done as an off-axis implant, e.g. at −/+7 degree, to avoid channeling (which increases the depth and straggle of the implant).

The dopants for the body region are now introduced, preferably by implantation. In this example, boron ions are implanted with a dose of 8E12 cm⁻² at an energy of 100 keV, using a tilt of −/+7 degree. These ions, once driven and annealed, will form the body region 122. A thermal step is now performed, either by RTA or in an oven, to drive and activate these dopants. This results in the intermediate structure of FIG. 6N.

At this point, as noted above, the oxide remnant hat 612″ is protruding up above the surface of the semiconductor material. This protruding remnant 612″ now serves an important function. A conformal layer of silicon nitride is now formed overall, e.g. to 30 nm thick, and anisotropically etched back by about the same amount. (Optionally, depending on the lateral spacing desired, the thickness of this layer can be as little as 10 nm thick, or as much as 100 nm thick. With a different process generation, these dimensions can be changed over a wider range.) This clears the nitride from flat surfaces, but leaves filaments 620 of nitride on the sides of the oxide remnant 612′. These filaments of nitride will play an important role as spacers. The height of the spacers will be about the same as the height of the hat, and their width will be the same as the deposited thickness of the layer. These steps result in the intermediate structure of FIG. 6O.

Note again that other dielectrics can optionally be used to make these spacers, but silicon nitride is the preferred material.

After the intermediate structure of FIG. 6O has been formed, the steps shown in FIGS. 6P-6R ensue. These include etching the contact, forming the p+ contact region, removing the nitride spacer, and forming source metal and drain metal.

After FIG. 6O, the spacers 120 define the boundaries of a recess etch. As before, an etch with moderate selectivity to oxide and nitride is preferably used, to etch (in this example) about 200 nm into the body region 122 and the RFP electrode 142. This results in the intermediate structure of FIG. 6P. Note that the edges of the recess are defined (near the gate trench) by the spacers 120, which themselves are self-aligned to the gate trench. It is also noted that the oxide layer surrounding the RFP trench is etched during the etching process due to its thin thickness. Alternatively, an optional additional etch is used to completely remove this oxide layer.

Next the p+ body contact region 123 will be formed. In this example, this is done by implanting and activating acceptor dopants, e.g. with about ˜2E15 cm⁻² of BF₂ at 20 keV (and no tilt), and also implanting about 2E12 cm⁻² of ¹¹B at 30 keV and a tilt of −/+7 degrees. These implant steps can be performed in either order, and are preferably followed by a rapid thermal anneal (RTA) at about 1000° C. for from 30 to 100 sec. This results in the intermediate structure of FIG. 6Q.

Next, the nitride spacers 120 are removed, and the gate trench top oxide is planarized. A Ti/TiN stack is now formed as a diffusion barrier, e.g. to 20 nm over 10 nm thickness, and a tungsten plug is formed. This is followed by deposition of e.g. Al:Si to a thickness of e.g. 4 microns, thus forming the source metal 102. This results in the intermediate structure of FIG. 6R. The drain metal 103 is formed similarly.

These steps are followed by conventional steps for passivation and for contact formation. In addition, as will be clear to those skilled in the art of semiconductor devices, peripheral structures will have been formed around the array of active devices.

Very specific parameters have been given above, to show concrete implementations of the disclosed innovative concepts. However, it should be understood that these specific parameters are not required to practice the invention. All of these parameters are merely examples, and will be modified by those of ordinary skill.

### ADVANTAGES

The disclosed innovations, in various embodiments, provide one or more of at least the following advantages. However, not all of these advantages result from every one of the innovations disclosed, and this list of advantages does not limit the various claimed inventions.
Power semiconductor devices with higher breakdown voltage;
Power semiconductor devices with lower on-resistance:
Power semiconductor devices with higher current density; and
Power semiconductor devices with lower cost.

According to some but not necessarily all embodiments, there is provided: a semiconductor device structure, comprising: a gate which is positioned in a first trench in semiconductor material, and capacitively coupled to control vertical conduction from a first-conductivity-type source region through a second-conductivity-type body region which is adjacent to said trench; metallic material which makes ohmic contact to the source region, and also to a second-conductivity-type body contact region which is continuous with the body region; wherein the body contact regions are separated from and closely self-aligned to the first trench; and recessed field plates positioned in respective second trenches.

According to some but not necessarily all embodiments, there is provided: a process for making a semiconductor device structure, comprising: forming first and second trenches in semiconductor material, and forming an insulated gate electrode in the first trench; forming a vertically protruding boss of solid material above the first trench, and forming sidewall spacers of a different material on the sidewalls of the vertically protruding boss; performing a recess etch on the semiconductor material at locations apart from the first trench, which are not underneath the sidewall spacers; forming second-conductivity-type body contact regions, surrounding the second trench, at locations which are not beneath the sidewall spacers; forming a metallic field plate in the second trench; and forming a metallic material which makes ohmic contact to the source region, and also to the second-conductivity-type body contact regions, and also to the metallic field plate; wherein the body contact regions are separated from and closely self-aligned to the first trench.

According to some but not necessarily all embodiments, there is provided: A semiconductor device structure, comprising: a gate which is positioned in a first trench in semiconductor material, and capacitively coupled to control emission of carriers from a first-conductivity-type source region, which is near a first surface of the semiconductor material, into a second-conductivity-type body region which is adjacent to said trench, and thence into a drift region therebelow; a first metallization which makes ohmic contact to the source region, and also to a second-conductivity-type body contact region which is located at the bottom of a recess and is continuous with the body region; wherein the body contact regions are separated from and closely self-aligned to the first trench; recessed field plates which are positioned in respective second trenches beneath the recess, and which are contacted by the metallic material; and a first-conductivity-type drain region near a second surface of the semiconductor material; whereby, when the voltage on the gate electrode permits emission of carriers from the source region, current flows substantially vertically between the source and drain region.

According to some but not necessarily all embodiments, there is provided: a semiconductor device structure, comprising: a gate which is positioned in a first trench in semiconductor material, and capacitively coupled to control emission of majority carriers from a first-conductivity-type source region into a second-conductivity-type body region which is adjacent to the trench; metallic material which makes ohmic contact to the source region, and also to a second-conductivity-type body contact region which is located in a tapered recess, and which is continuous with the body region; wherein the body contact region is laterally separated from the first trench by the source region, and the source region has a sloping side surface at the tapered recess, and the body contact region is self-aligned to the first trench; and further comprising recessed field plates positioned in respective second trenches under the tapered recess, and contacted by the metallic material.

According to some but not necessarily all embodiments, there is provided: a process for making a semiconductor device structure, comprising: forming first and second trenches in semiconductor material, and forming an insulated gate electrode in the first trench; forming a vertical protrusion of a first material above the first trench, and forming sidewall spacers of a different material on the sidewalls of the vertical protrusion; performing a recess etch on the semiconductor material at locations apart from the first trench, which are not underneath the sidewall spacers; forming second-conductivity-type body contact regions, surrounding the second trench, at locations which are not beneath the sidewall spacers; forming a field plate in the second trench; and forming a metallic material which makes ohmic contact to the source region, and also to the second-conductivity-type body contact regions, and also to the field plate; wherein the body contact regions are separated from and closely self-aligned to the first trench.

According to some but not necessarily all embodiments, there is provided: during fabrication of a trench transistor device, a vertical protrusion (or “hat”) of oxide (or other suitable material) can be left in place above the trench which contains the transistor gate. This vertical protrusion is self-aligned to the gate trench, and is used to define the positions of sidewall spacers (made e.g. of silicon nitride). These sidewall spacers define a space outward from the edge of the gate trench; by performing a recess etch which is delimited by these sidewall spacers, the resistance of the source contact and the body contact is minimized. The spacing between the gate trench and the recessed contact can therefore be controlled and minimized, which improves density without degrading on-resistance nor breakdown voltage. The resulting device is different from previous devices, because lateral dimensions around the gate are self-aligned. Normally some degree of unpredictable misalignment will occur in a state-of-the-art microelectronic wafer (and in the dies which are part of the wafer). However, where self-alignment is used, this variation essentially disappears. The lateral distance between the walls of the gate trench and the recess over the field plate trench is NOT defined by lithography in any way, and does not show the small misalignments resulting from lithography. This means that the devices built according to the present application are different from all previous devices of this kind; but the difference is most easily understood by reviewing the process steps.

According to some but not necessarily all embodiments, there is provided: Structures and fabrication methods for increasing the density of trench transistor devices and the like. During fabrication of a trench transistor device, a vertical protrusion (or “hat”) of oxide is left in place above the gate trench. This vertical protrusion is self-aligned to the gate trench, and is used to define the positions of sidewall spacers (made e.g. of silicon nitride). These sidewall spacers define a space outward from the edge of the gate trench; by performing a recess etch which is delimited by these sidewall spacers, the resistance of the source contact and the body contact is minimized. The spacing between the gate trench and the recessed-contact field-plate trench can therefore be minimized and well controlled, which improves density without degrading on-resistance nor breakdown voltage.

Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

It is understood that numerous combinations of the above embodiments can be realized.

All the above variants of the structure can be realized in stripe or cellular layout such as square, rectangular, hexagonal or circular layouts.

Even though the embodiments above are for MOSFET structures, the disclosed inventions are also applicable to many devices such as Insulated Gate Bipolar Transistors (IGBTs), thyristors, MCTs (MOS-controlled thyristors), and other solid state switches that can block voltages. The disclosed inventions are believed to be especially advantageous with devices which incorporate a trench-gated transistor.

In addition to silicon material, other semiconductor materials or combination of materials, such as e.g. SiC and GaN, can be used to realize the above structures.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

Those of ordinary skill in the relevant fields of art will recognize that other inventive concepts may also be directly or inferentially disclosed in the foregoing. The claims as filed are intended to be as comprehensive as possible, and NO subject matter is intentionally relinquished, dedicated, or abandoned.

1. A semiconductor device structure, comprising:
a gate which is positioned in a first trench in semiconductor material, and capacitively coupled to control vertical conduction from a first-conductivity-type source region through a second-conductivity-type body region which is adjacent to said trench;
a first metallization which makes ohmic contact to the source region, and also to a second-conductivity-type body contact region which is continuous with the body region;
wherein the body contact regions are separated from and closely self-aligned to the first trench; and
recessed field plates positioned in respective second trenches and contacted by the metallic material.

2. The semiconductor device structure of claim 1, wherein the gate is made of a polycrystalline semiconductor material.

3. The semiconductor device structure of claim 1, wherein the field plate is made of a polycrystalline semiconductor material.

4. The semiconductor device structure of claim 1, wherein the gate is separated from the first metallization by a thick dielectric layer.

5. The semiconductor device structure of claim 1, wherein the gate has a split poly configuration.

6. The semiconductor device structure of claim 1, wherein at least one of the recessed field plates has a split poly configuration.

7. The semiconductor device structure of claim 1, wherein both the gate and at least one of the recessed field plates have a split poly configuration.

8. The semiconductor device structure of claim 1, wherein the first conductivity type is n-type.

9. The semiconductor device structure of claim 1, wherein the gate is capacitively coupled to control vertical conduction between the source region and a drain diffusion of said first conductivity type.

10. The semiconductor device structure of claim 1, wherein the gate is insulated from the semiconductor material by a thin layer of silicon dioxide.

11. The semiconductor device structure of claim 1, wherein the semiconductor material is silicon, and the gate is insulated from the semiconductor material by a thin layer of grown silicon dioxide.

12. A semiconductor device structure, comprising:
a gate which is positioned in a first trench in semiconductor material, and capacitively coupled to control emission of carriers from a first-conductivity-type source region, which is near a first surface of the semiconductor material, into a second-conductivity-type body region which is adjacent to said trench, and thence into a drift region therebelow;
a first metallization which makes ohmic contact to the source region, and also to a second-conductivity-type body contact region which is located at the bottom of a recess and is continuous with the body region;
wherein the body contact regions are separated from and closely self-aligned to the first trench;
recessed field plates which are positioned in respective second trenches beneath the recess, and which are contacted by the metallic material; and
a first-conductivity-type drain region near a second surface of the semiconductor material;
whereby, when the voltage on the gate electrode permits emission of carriers from the source region, current flows substantially vertically between the source and drain region.

13. The semiconductor device structure of claim 12, wherein the drift region has the first conductivity type.

14. The semiconductor device structure of claim 12, wherein the first metallization is separated from the second-conductivity-type body contact region by a layer of diffusion barrier material.

15. The semiconductor device structure of claim 12, wherein the gate is insulated from the semiconductor material by a thin layer of silicon dioxide.

16. The semiconductor device structure of claim 12, wherein the semiconductor material is silicon, and the gate is insulated from the semiconductor material by a thin layer of grown silicon dioxide.

17. The semiconductor device structure of claim 12, wherein the gate is made of a polycrystalline semiconductor material.

18. The semiconductor device structure of claim 12, wherein the field plate is made of a polycrystalline semiconductor material.

19. The semiconductor device structure of claim 12, wherein the gate has a split poly configuration.

20-23. (canceled)

24. A semiconductor device structure, comprising:
a gate which is positioned in a first trench in semiconductor material, and capacitively coupled to control emission of majority carriers from a first-conductivity-type source region into a second-conductivity-type body region which is adjacent to the trench;
metallic material which makes ohmic contact to the source region, and also to a second-conductivity-type body contact region which is located in a tapered recess, and which is continuous with the body region;
wherein the body contact region is laterally separated from the first trench by the source region, and the source region has a sloping side surface at the tapered recess, and the body contact region is self-aligned to the first trench; and further comprising
recessed field plates positioned in respective second trenches under the tapered recess, and contacted by the metallic material.

25-47. (canceled)
